(19) United States
(12) Patent Application Publication
(10) Pub. No.: US 2009/0045386 A1
(43) Pub. Date: Feb. 19, 2009

(54) Phase-change memory element

(75) Inventor: Frederick T. Chen, Hsinchu (TW)

Correspondence Address: BIRCH STEWART KOLASCH & BIRCH, PO BOX 747, FALLS CHURCH, VA, 22040-0747, US

(73) Assignees: Industrial Technology Research Institute; Powerchip Semiconductor Corp.; Nanya Technology Corporation; ProMOS Technologies Inc.; Winbond Electronics Corp.

(21) Appl. No.: 11/889,522

(22) Filed: Aug. 14, 2007

(51) Int. Cl. H01L 45/00; G11C 11/00

(52) U.S. Cl. 257/3; 365/163; 257/E45.002

(57) ABSTRACT

A phase-change memory element. The phase-change memory element comprises a first electrode and a second electrode. A first phase change layer is electrically coupled to the first electrode. A second phase change layer is electrically coupled to the second electrode. A conductive bridge is formed between and electrically coupled to the first and second phase change layers.

### BACKGROUND OF THE INVENTION

1. Field of the Invention

The invention relates to a memory element, and more particularly to a phase-change memory element.

2. Description of the Related Art

Phase-change memory is a scalable, high-speed non-volatile memory. Targeted applications are typically in mobile devices which require low power consumption, and hence, minimal programming currents. A phase-change memory cell should be designed with several goals in mind: low programming current, low voltage, higher reliability, and faster phase transformation speed. These requirements often set contradictory requirements on feature size, but a careful choice and arrangement of materials used for the components can often widen the tolerance.

An additional performance feature that is sometimes overlooked is reliability. For a phase-change memory cell, this means the ability to complete the desired phase-change within the programming operation time. Programming is carried out by applying a voltage pulse or current pulse to a phase-change memory cell, of a given duration and amplitude. The result is to heat the active region of the phase-change memory cell to a certain degree. The phase-change rate is critically dependent on the temperature. Temperature uniformity is crucial to guaranteeing that all parts of the active phase-change region consistently complete the phase-change. Hence, in addition to high heating efficiency, uniform heating is equally if not more important.

In order to maintain low-voltage operation, it is desirable to first use a minimal amount of phase-change material in the current path. The chalcogenide phase-change material is the dominant resistance in the circuit. Voltage is also reduced by reducing programming current.

In order to reduce the programming current, the most straightforward way is to shrink the heating area. In reality, however, cooling becomes significant for smaller structures, and loss to surroundings becomes more important due to increasing surface/volume ratio. As a result, the required current density must increase as heating area shrinks. This poses an electromigration concern for reliability. It is important to enhance heating for a given nominal current density, by minimizing heat loss to the surroundings. Thermal uniformity is also achieved in this way.

In one structure disclosed in the prior art, U.S. Pat. No. 5,789,758 assigned to Micron (“Chalcogenide Memory Cell with a Plurality of Chalcogenide Electrodes”), a pore is positioned in a dielectric layer positioned between an upper and lower chalcogenide electrode, both of which have greater cross-sectional areas than the pore. The pore is filled with chalcogenide material. Hence the phase-change takes place in the pore. This creates two issues. First, the resistance will be very high, due to the presence of high-resistance chalcogenide with narrow cross-sectional area. Second, the heating loss to the dielectric on the side is not insignificant. Most CVD dielectrics can go down to 0.7 W/m-K under tailored deposition conditions. More exotic materials which are porous in nature can have very low thermal conductivity (˜0.1 W/m-K), but these materials also suffer from chemical and mechanical degradation upon heating to the required temperatures for phase change.

In another structure disclosed in the prior art, US Patent Application 20060157689 (“Forming a carbon layer between phase change layers of a phase change memory”), a carbon-containing layer undergoes localized heating from a filament in the lower phase change layer to produce a conductive channel between the lower and upper phase change layers. It is not known in advance where the filament may form and it is also not known in advance how wide the channel in the carbon-containing layer will be. Hence, it is hard to design a cell based on this phenomenon.

Therefore, it is necessary to develop a phase-change memory to solve the previously described problems.

### BRIEF SUMMARY OF THE INVENTION

An exemplary embodiment of a phase-change memory element comprises a first electrode and a second electrode. A first phase change layer is electrically coupled to the first electrode. A second phase change layer is electrically coupled to the second electrode. A conductive bridge is formed between and electrically coupled to the first and second phase change layers.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1a-1f are cross sections of a method of fabricating a phase-change memory element according to an embodiment of the invention.

FIGS. 2 and 3 are cross sections of phase-change memory elements according to some embodiments of the invention.

### DETAILED DESCRIPTION OF THE INVENTION

A normal metallic electrical contact is a high thermal conductivity material, which allows it to act as an effective sink. In the vicinity of the contact, the temperature rapidly drops from the programming temperature to the ambient temperature. The difference can be on the order of 1000° C. Any phase-change material in the vicinity of the contact therefore suffers from non-uniform completion of phase-change. Since a metallic electrical contact is an effective heat sink, it can be expected that it will be difficult to guarantee phase change completion at the contact and at some distance. It is difficult to guarantee 100% completion of the phase-change, especially the coolest regions near the metal contact, without using an excessively long programming time. The key is to use a non-insulating material that does not act as heat sink, i.e., with a low thermal conductivity.

Among the materials used in the phase-change memory cell, that with the lowest thermal conductivity is chalcogenide (such as Ge2Sb2Te5). The thermal conductivity of the material is notably low, ˜0.2-0.3 W/m-k, due to the 20% presence of vacancies in the crystalline (fcc phase) microstructure. Ideally, the active phase-change region is surrounded as much as possible by the material.

The following description is of the best-contemplated mode of carrying out the invention. This description is made for the purpose of illustrating the general principles of the invention and should not be taken in a limiting sense. The scope of the invention is best determined by reference to the appended claims.

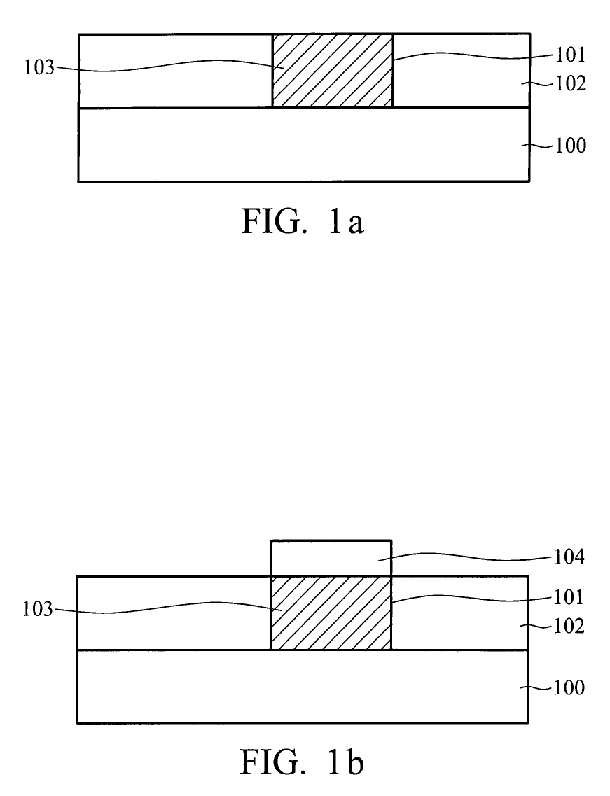

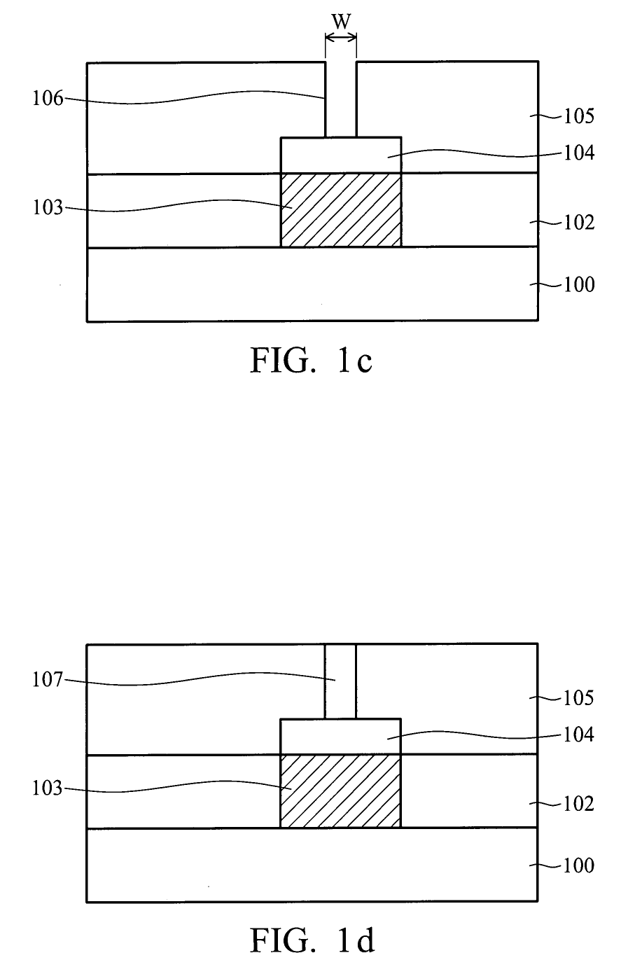

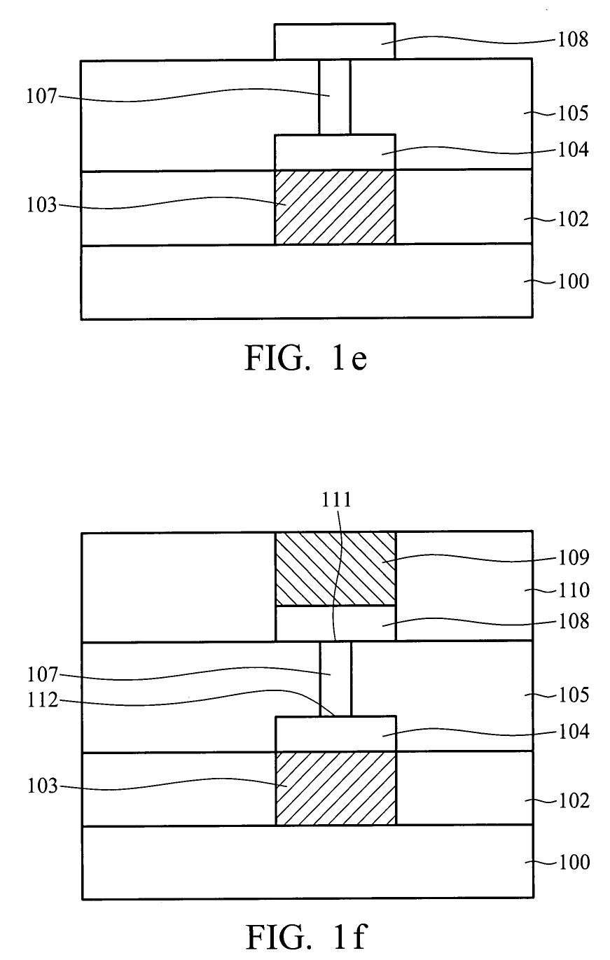

First, referring to FIG. 1a, a substrate 100 with a dielectric layer 102 having an opening 101 formed thereon is provided, and a first electrode 103 serving as bottom electrode fills with the opening 101 exposing the top surface of the first electrode 103. Particularly, the substrate 100 can be a substrate employed in a semiconductor process, such as silicon substrate. The substrate 100 can be a substrate comprising a bipolar or metal oxide semiconductor (CMOS) transistor, isolation structure, diode, or capacitor (device not shown). The accompanying drawings show the substrate 100 in a plain rectangle in order to simplify the illustration. Suitable material for the first electrode 103 can be Al, W, Mo, Ti, TiN, TiW or TaN. The dielectric layer 102 can be a silicon-containing compound, such as silicon nitride or silicon oxide.

Next, referring to FIG. 1b, a first phase change layer 104 is formed on and electrically coupled the first electrode 103, wherein first phase change layer 104 can comprise In, Ge, Sb, Te or combinations thereof, such as GeTe, GeSb, SbTe, GeSbTe or InGeSbTe.

Next, referring to FIG. 1c, a second dielectric layer 105 is formed on the first dielectric layer 102 and the first phase change layer 104, and a opening 106 is formed to pass through the second dielectric layer 105 exposing the top surface of the first phase change layer 104. The second dielectric layer 105 can be a silicon-containing compound, such as silicon nitride or silicon oxide. It should be noted that the opening 106 can have a width W less than the resolution limit of photolithography process.

Next, referring to FIG. 1d, a conductive bridge 107 is filled into the opening 106 and electrically coupled the first phase change layer 104. The conductive bridge 107 can be Al, W, Mo, Ti, TiN, TiW or TaN and have a thickness of 5-100 nm, or between 20-40 nm.

Next, referring to FIG. 1e, a second phase change layer 108 is formed on the second dielectric layer 105 and the conductive bridge 107 and electrically coupled the conductive bridge 107, wherein the second phase change layer 108 can comprise In, Ge, Sb, Te or combinations thereof, such as GeTe, GeSb, SbTe, GeSbTe or InGeSbTe.

Finally, referring to FIG. 1f, a second electrode 109 as a top electrode is formed on and electrically coupled to the second phase change layer 108, and a third dielectric layer 110 is formed to surround the second electrode 109. Suitable material of the second electrode 109 can be Al, W, Mo, Ti, TiN, TiW or TaN. In this embodiment, the conductive bridge 107 filled with the opening 106 electrically couples the first and second phase change layers 104 and 108. The opening 106 has a narrow cross-section area in the current path. Since the opening is filled with metal instead of chalcogenide material, the voltage drop across the opening is negligible. The phase-change materials directly adjacent to both sides of the opening are heated simultaneously. Further, the high conductivity metal acts a thermal bridge 107 rather than a heat sink, it helps maintain equal temperature at both end. The phase-change is mostly surrounded by additional chalcogenide material which, being of low thermal conductivity, acts as a thermal insulator, containing heat mostly in the active phase-change region.

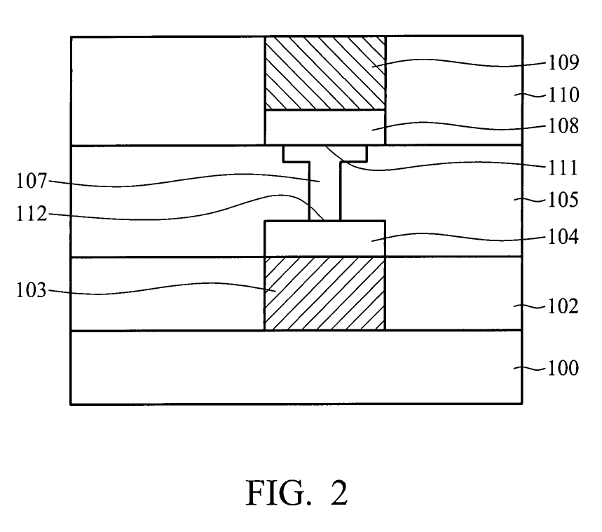

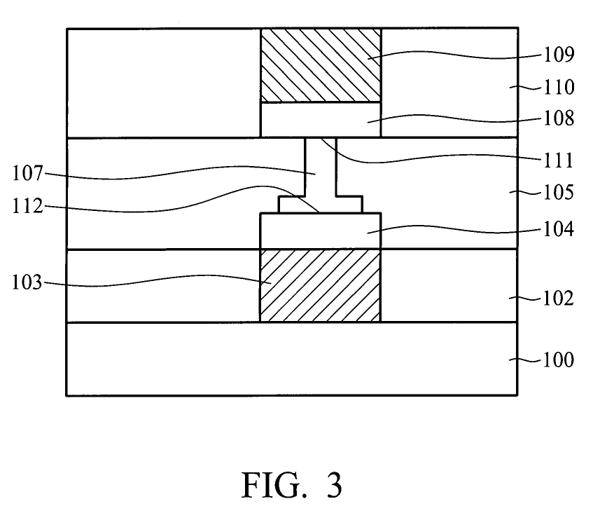

Referring to FIG. 1f, there are a first cross-section area 112 between the first phase change layer 104 and the conductive bridge 107 and a second cross-section area 111 between the second phase change layer 108 and the conductive bridge 107. In this embodiment, the dimension of the first and second cross-section areas 111 and 112 are the same. In some embodiments of the invention, the dimension of the first and second cross-section areas 111 and 112 can be different. The structure may be a opening with a taper, a cup-shaped trench, or T-shaped trench (referring to FIGS. 2 and 3), filled with metal. As a result, the current density at one chalcogenide-bridge interface is higher than the other. The phase-change therefore only takes place at the narrower end not the wider end. The presence of the inactive chalcogenide (wider end) serves as a thermal barrier layer. Without it, the metal structure would be an effective heat sink, which would not only make heating more difficult, but also lead to much less uniform phase-change.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase-change memory element, comprising
a first electrode and a second electrode;
a first phase change layer electrically coupled to the first electrode;
a second phase change layer electrically coupled to the second electrode; and
a conductive bridge formed between and electrically coupled to the first and second phase change layers.

2. The phase-change memory element as claimed in claim 1, wherein the first and second electrodes respectively comprise Al, W, Mo, Ti, TiN, TiW or TaN.

3. The phase-change memory element as claimed in claim 1, wherein the conductive bridge comprises Al, W, Mo, Ti, TiN, TiW or TaN.

4. The phase-change memory element as claimed in claim 1, wherein the first and second phase change layers respectively comprise In, Ge, Sb, Te or combinations thereof.

5. The phase-change memory element as claimed in claim 1, wherein the first and second phase change layers respectively comprise GeTe, GeSb, SbTe, GeSbTe or InGeSbTe.

6. The phase-change memory element as claimed in claim 1, further comprising:
a first cross-section area formed by intersection of the first phase change layer and the conductive bridge; and
a second cross-section area formed by intersection of the second phase change layer and the conductive bridge.

7. The phase-change memory element as claimed in claim 6, wherein the dimensions of the first and second cross-section areas are the same.

8. The phase-change memory element as claimed in claim 6, wherein the dimensions of the first and second cross-section areas are different.

9. The phase-change memory element as claimed in claim 6, wherein at least one of the first and second cross-section areas has a dimension less than the resolution limit of photolithography process.

10. The phase-change memory element as claimed in claim 1, further comprising a dielectric layer with an opening, wherein the conductive bridge fills the opening.
